(19) United States
(12) Patent Application Publication
(10) Pub. No.: US 2004/0165427 A1
(43) Pub. Date: Aug. 26, 2004

(54) Magnetic memories having magnetic tunnel junctions in recessed bit lines and/or digit lines and methods of fabricating the same

(76) Inventor: Won-cheol Jeong, Seoul (KR)

Correspondence Address: David K. Purks, Myers Bigel Sibley & Sajovec, Post Office Box 37428, Raleigh, NC, 27627, US

(21) Appl. No.: 10/778,971

(22) Filed: Feb. 13, 2004

(30) Foreign Application Priority Data
Feb. 20, 2003 (KR) 10-2003-0010743

(51) Int. Cl. G11C 11/14

(52) U.S. Cl. 365/171

(57) ABSTRACT

The present invention provides a magnetic memory having magnetic tunnel junction and a method of fabricating the same. The magnetic memory includes a plurality of digit lines, a plurality of a bit line intersecting over on a top surface of the digit lines and a magnetic tunnel junction interposed between the bit line and the digit lines. In this case, at least one among the bit line and digit lines intersect bumpily the magnetic tunnel junction. In other words, a bottom surface of the bit line may be disposed lower in a lateral part of the magnetic tunnel junction than in a top surface of the magnetic tunnel junction. In addition, a top surface of the digit line may be disposed higher in a lateral part than in a bottom surface of the magnetic tunnel junction. Consequently, magnetic field strength applied to a free layer may be increased without increasing electric current.

### RELATED APPLICATION

This U.S. nonprovisional patent application claims priority under 35 U.S.C. § 119 to Korean Patent Application No. 10-2003-0010743, filed on Feb. 20, 2003, in the Korean Intellectual Property Office, which is hereby incorporated herein by reference in its entirety as if set forth fully herein.

### FIELD OF THE INVENTION

The present invention relates to memory devices and related fabrication methods, and more particularly, to semiconductor memory devices having magnetic tunnel junctions (MTJs) and fabrication methods thereof.

### BACKGROUND OF THE INVENTION

Some types of semiconductor memory devices are SRAM (Static Random Access Memory), DRAM (Dynamic Random Access Memory), flash memory, and ferromagnetic RAM. These memory devices can have significantly different operational properties, such as those shown below in Table 1, and accordingly may be appropriate for use in some electronic devices, but not others.

TABLE 1

| | SRAM | DRAM | FLASH | FeRAM | MRAM |
|---|---|---|---|---|---|
| READ | High speed | Half speed | High speed | Half speed | Half˜High |
| | | | | | speed |
| WRITE | High speed | Half speed | Low speed | Low speed | Half˜High |
| | | | | | speed |
| Non-volatility | None exist | None exist | Yes | Half | Yes |
| Refresh | Not needed | Need | Not needed | Not needed | Not needed |
| Size of Unit Cell | Large | Small | Small | Half | Small |
| Low Voltage | Possible | Limited | Impossible | Limited | Possible |
| for Operation | | | | | |

FIG. 1A is a circuit diagram illustrating a unit cell of a conventional full CMOS SRAM including a P-channel MOSFET used as a pull-up device. Such SRAM devices may provide high speed read and write operations and/or low power consumption. However, as shown in FIG 1A, the unit cell has six transistors, which may limit the integration density of such unit cells.

FIG. 1B is a circuit diagram of a cell array of a conventional DRAM. The unit cell of the DRAM has one transistor and one capacitor, the DRAM may have a unit cell area of about 10 F², which can be much smaller than the unit cell area of the SRAM (“F” indicates a minimum feature size). Accordingly, the DRAM may have a higher unit cell integration density than the SRAM. In contrast to SRAMs, DRAMs may need a refresh operation every several milliseconds to prevent loss of information due to, for example, leakage of stored charge.

Some electronic devices need non-volatile memory in which stored information is maintained after power to the memory is removed. Flash memories and ferroelectric memories may be used to provide non-volatile memory in such electronic devices.

FIG. 1C is a circuit diagram of a cell array of a conventional NAND flash memory. Because the illustrated NAND flash memory does not include a cell capacitor and a contact in every unit cell, it may have a unit cell area of 4˜8 F², which may be smaller than the unit cell area of a DRAM. Accordingly, NAND flash memory may have a higher integration density than DRAM devices. However, NAND flash memory may need a high driving voltage, such as, for example from 5 to 12 volts in a write mode, and may have a low erase speed. Also, integration density of the NAND flash memory may be reduced by the use of a pumping circuit to elevate the driving voltage. Flash memory may also provide a limited number of rewritable operations, such as, for example 105 to 106 rewrites.

A ferroelectric memory may use, for example, one transistor and one capacitor per unit cell, similar to DRAMs. A ferroelectric memory can be made non-volatile by using a ferroelectric material in the capacitor. Read operations may have a destructive affect on information in memory cells, so that a rewrite operation may be needed after a read operations. Ferroelectric memories may also provide a limited number of write operations, and may provide relatively average memory access speeds. Ferroelectric memories can be difficult to manufacture because of, for example, reactivity of the ferroelectric materials with hydrogen, high temperatures that may be used for annealing processes, and scalability and cell voltage issues.

Magnetic RAM or Magnetoresistive RAM (MRAM) can be used to provide non-volatile memory that may not be write cycle limited, may allow high integration density, may provide fast memory access operations, and may use a lower voltage relative to ferroelectric memories.

A conventional MRAM is hereafter described with reference to FIGS. 2 to 4. FIG. 2 is a plan view of a part of a cell array of a conventional MRAM. FIG. 3 is a sectional view taken along line I-I′ of FIG. 2. FIG. 4 is a perspective view of a structure of a conventional MRAM with a Magnetic Tunnel Junction (MTJ).

Referring to FIGS. 2 to 4, a device isolation region 12 defines an active region 11 in a semiconductor substrate 10. A plurality of gate electrodes or word lines 15 intersect over the active regions 11 and the device isolation region 12. A pair of gate electrodes 15 perpendicularly intersects over each of the active regions 11, so that if the active regions 11 are arranged in a row direction (X-axis direction), the gate electrodes 15 are arranged in a column direction (Y-axis direction). A common source region 16s is formed in the active region 11 between the gate electrodes 15, and the drain regions 16d are formed in the active regions 11 on both sides of the common source region 16s. A cell transistor of the MRAM is thereby arranged at an intersection point of the active region 11 and the gate electrode 15.

A whole surface of the resultant substrate including the cell transistor is covered with an interlayer insulating film 20. A plurality of digit lines 30 are parallel to the gate electrodes 15 in the interlayer insulating film 20. A plurality of bit lines 50 are formed parallel to the active region 11 to intersect over the gate electrode 15, on the interlayer insulating film 20 and over the digit lines 30. A magnetic tunnel junction (MTJ) 40 is formed between the bit line 50 and the digit line 30. A lower electrode 35 is between the MTJ 40 and the digit line 30 and extends to an upper portion of the drain region 16d. The MTJ 40 contacts a lower surface of the bit line 50 and an upper surface of the lower electrode 35. Vertical wiring 25 is formed in the interlayer insulating film 20 and electrically connects the drain region 16d to the lower electrode 35. The vertical wiring 25 can also include a plurality of plugs having a sequentially stacked structure. A source line 28 is connected to an upper surface of the common source region 16s via a source plug 26 that is connected therebetween.

The MTJ 40 may have a sequentially stacked structure of a pinning layer 42, a fixed layer 44, an insulating layer 46 and a free layer 48. The resistance of the MTJ 40 can substantially vary based on the relative magnetization directions of the fixed layer 44 and the free layer 48 (e.g., same or opposite magnetization directions). Consequently, resistivity of the MTJ 40 can be used to indicate information in a MRAM. Generally, the magnetization direction of the fixed layer 44 is not varied during a reading/writing operation. A multi-layered or single layered pinning layer 42 can fix the magnetization direction of the fixed layer 44. The magnetization direction of the free layer 48 can vary relative to the magnetization direction of the fixed layer 44. For example, the magnetization direction of the free layer 48 can be the same or the reverse of the fixed layer 44.

Information may be read from a cell by selecting the corresponding word line 15 and bit line 50, and then measuring current flowing therethrough. Current magnitude may substantially vary depending on the relative magnetization directions of the fixed layer 44 and the free layer 48. The relative current magnitude can represent stored information (e.g., binary values). Information can be written to a cell by varying the magnetization direction of the free layer 48, such as by creating a magnetic field from the current flowing through the bit line 50 and the digit line 30.

### SUMMARY OF THE INVENTION

According to various embodiments of the present invention, a magnetic memory includes a digit line, a bit line, and a magnetic tunnel junction. The bit line has a recessed portion at an intersection with the digit line. The magnetic tunnel junction is at least partially disposed in the recessed portion of the bit line.

In some further embodiments of the present invention, a majority of a side surface of the magnetic tunnel junction is disposed in the recessed portion of the bit line. The magnetic memory may include a plurality of digit lines, a plurality of bit lines with recessed portions, and a plurality of magnetic tunnel junctions at least partially disposed in the recessed portions of the bit lines. The magnetic memory may include a first insulation layer between the bit line and the magnetic tunnel junction. The first insulation layer may define an opening that exposes at least a portion of a first surface of the magnetic tunnel junction. The bit line may contact the first surface of the magnetic tunnel junction through the opening in the first insulating layer. The magnetic memory may include a second insulating layer between the bit line and a major portion of the first insulating layer. The second insulation layer has a planar exposed surface on which the bit line is formed, and defines an opening through which the bit line is directly on the first insulating layer in a region adjacent to and over the magnetic tunnel junction.

According to various other embodiments of the present invention, a magnetic memory includes a digit line, a bit line, and a magnetic tunnel junction. The digit line has a recessed portion at an intersection with the bit line. The magnetic tunnel junction is at least partially disposed in the recessed portion of the digit line.

According to yet other embodiments of the present invention, a magnetic memory includes a digit line, a bit line, and a magnetic tunnel junction. The bit line and the digit line each have an oppositely recessed portion at an intersection of the bit line and the digit line. The magnetic tunnel junction is at least partially disposed in the recessed portion of the bit line and in the recessed portion of the bit line.

It is to be understood that both the foregoing summary of the present invention and the following detailed description of the present invention are exemplary and explanatory and are intended to provide further explanation of the invention as claimed.

### BRIEF DESCRIPTION OF THE DRAWINGS

FIG. 1A is a circuit diagram illustrating a unit cell of a CMOS type SRAM according to the prior art.

FIG. 1B is a circuit diagram illustrating a cell array of a DRAM according to the prior art.

FIG. 1C is a circuit diagram illustrating a cell array of a NAND flash memory according to the prior art.

FIG. 2 is a plan view illustrating a part of a cell array of a Magnetic Random Access Memory (MRAM) according to the prior art.

FIG. 3 is a process cross-sectional view illustrating the cell array of a MRAM according to the prior art.

FIG. 4 is a perspective view for illustrating a structure of a MRAM with Magnetic Tunnel Junctions (MJTs) according to the prior art.

FIG. 5 is a circuit diagram illustrating a cell array of a MRAM according to various embodiments of the present invention.

FIGS. 6 and 7 are cross-sectional views illustrating a cell array of a MRAM according to some embodiments of the present invention.

FIG. 8 to FIG. 10 are perspective views illustrating a MRAM with MJTs according to some embodiments of the present invention.

FIG. 11 to FIG. 16 are cross-sectional views illustrating operations for fabricating a MRAM having MJTs according to some embodiments of the present invention.

FIG. 17 and FIG. 18 are cross-sectional views illustrating a MRAM having MJTs according to other embodiments of the present invention.

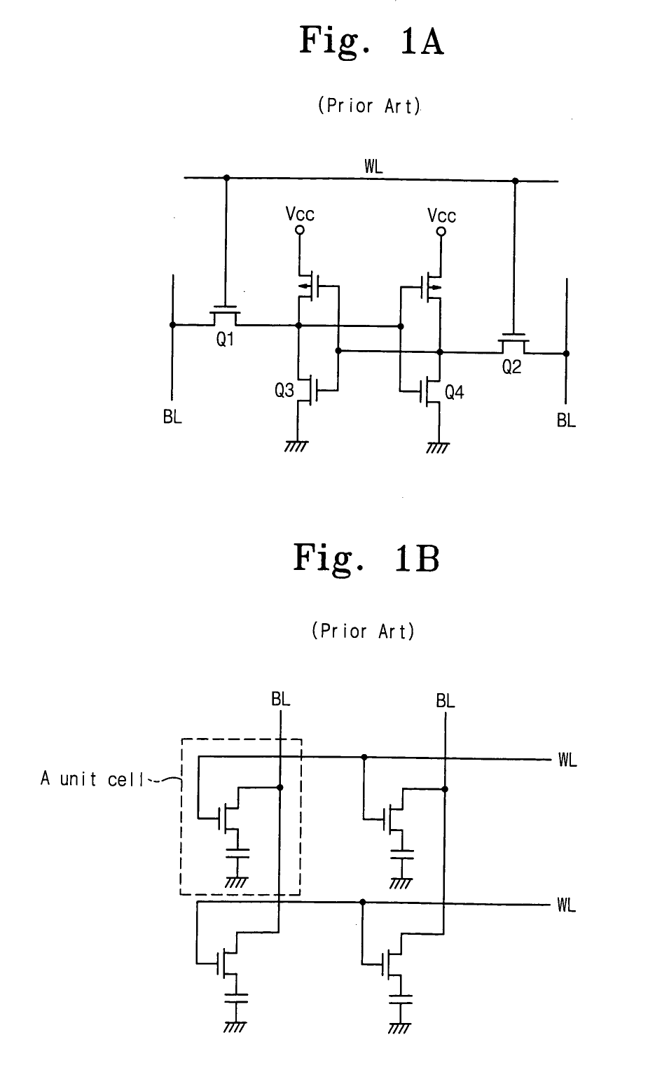

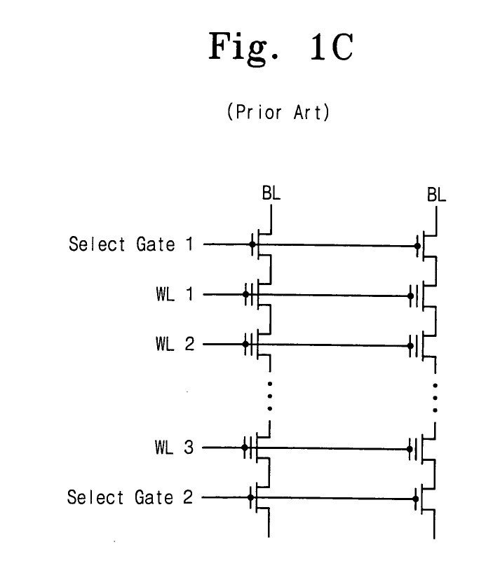

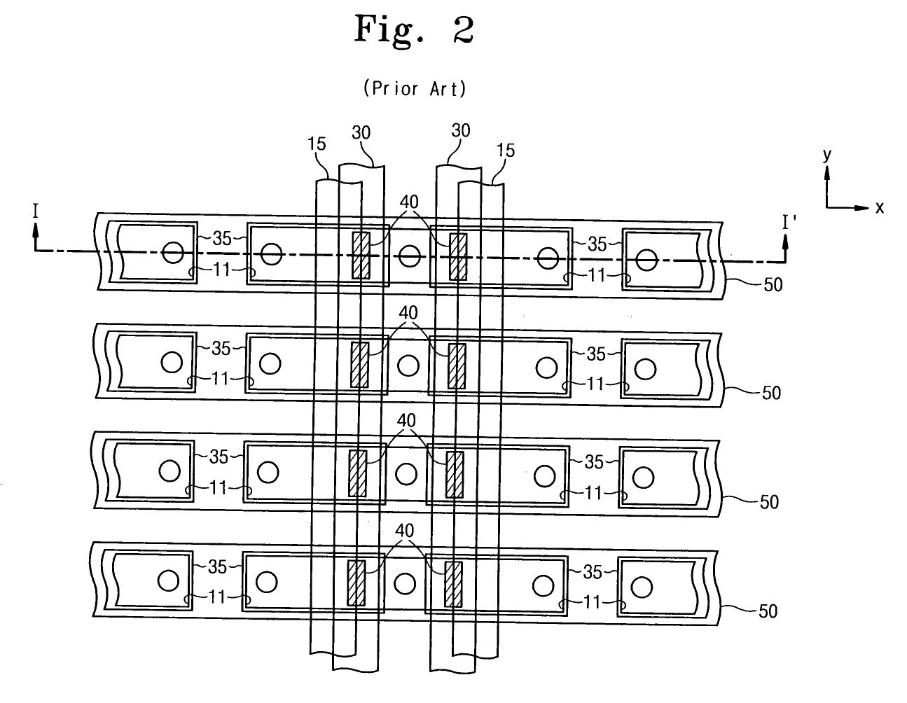

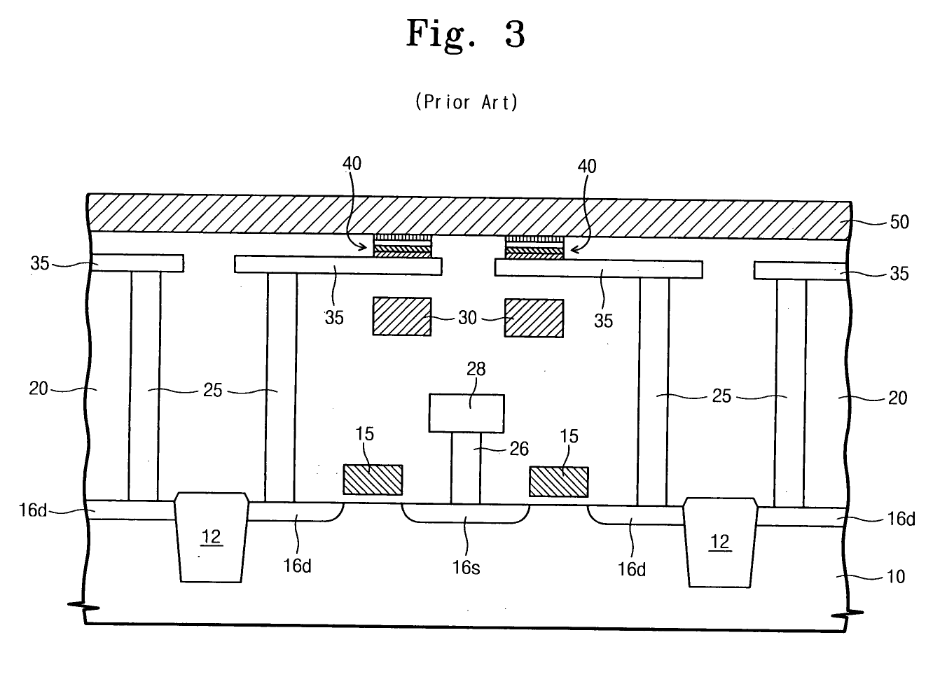

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will also be understood that the sizes and thickness of layers are not shown to scale, and in some instances they have been exaggerated for purposes of explanation.

Furthermore, relative terms, such as “lower” and “upper”, may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” of other elements would then be oriented on “upper” of the other elements. The exemplary term “lower”, can therefore, encompass both an orientation of lower and upper, depending of the particular orientation of the figure.

According to various embodiments of the present invention, a unit cell of a Magnetic Random Access Memory (MRAM) includes a digit line, a bit line, and a magnetic tunnel junction that is interposed therebetween. MRAM cells can be arranged in two dimensions as well as in three dimensions. For example, more than one plane of MRAM cells may be provided in an MRAM. A MRAM cell may include a tunneling magneto-resistive (TMR) element on a semiconductor substrate with, or without, other transistors. A MRAM cell can be connected to other functional circuits, such as to transistors, through conductors formed by, for example, wire bonding, flip-chip bonding, and solder bump.

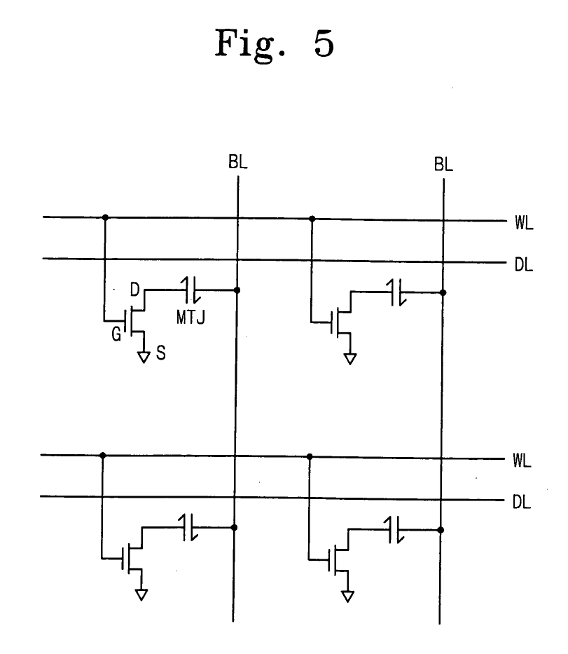

FIG. 5 is a circuit diagram of a part of a cell array of a MRAM according to various embodiments of the present invention. Referring to FIG. 5, a plurality of cell transistors are arranged two-dimensionally in row and column directions. The cell transistors may be MOSFETs (Metal-Oxide-Semiconductor Field Effect Transistors) with a source region (S) and a drain region (D) on a semiconductor substrate, and may be connected to one another by a plurality of word lines (WL) and bit lines (BL). The word lines (WL) and the bit lines (BL) can be respectively arranged in the row and the column directions, and are respectively connected to gates (G) and drains (D) of the cell transistors. Magnetic tunnel junctions (MTJs) are between the bit lines (BL) and the cell transistors, and provide information storage in the MRAM.

A plurality of digit lines (DL) are arranged to intersect the cell transistors in a parallel direction to the word lines (WL). Thus, the word lines (WL) and the digit lines (DL) both intersect the bit lines (BL). As used herein, “intersect” can mean to underlay or overlay another element or structure but separated therefrom. The bit line (BL), the digit line (DL), and the word line (WL) may be used to select a particular cell transistor. The word line (WL) and the digit line (DL) select cell transistors that are arranged in the same direction (e.g., connect transistors in rows). The bit line (BL) connects cell transistors to one another in a perpendicular direction to the word line (WL) and the digit line (DL) (e.g., connect transistors in columns).

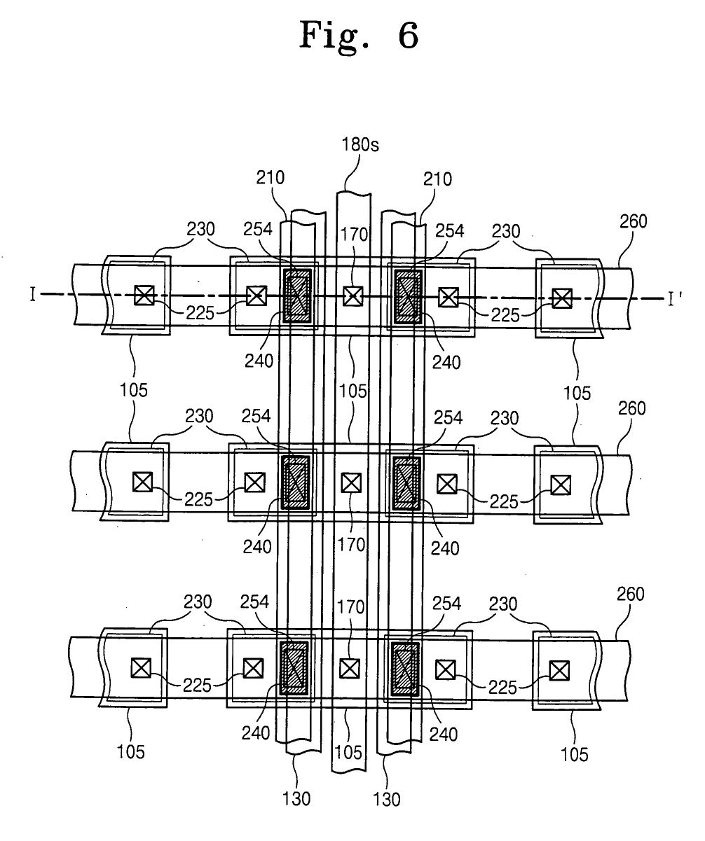

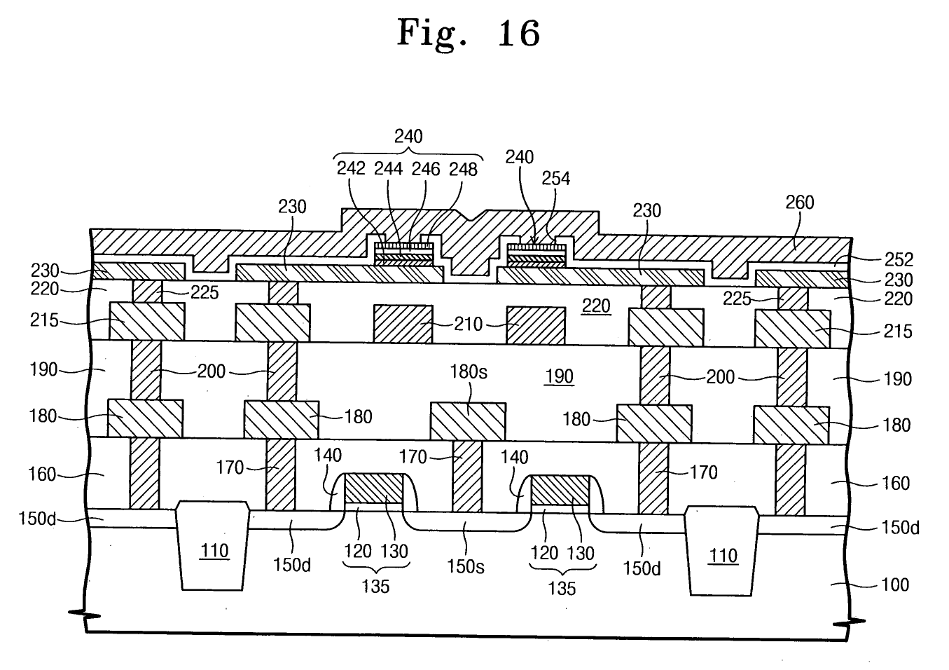

FIG. 6 is a plan view of a part of a cell array of MRAM according to first embodiments of the present invention. In addition, FIG. 16 is a sectional view, taken along lines I-I′ of FIG. 6. Referring to FIGS. 5, 6 and 16, device isolation regions 110 are formed in a semiconductor substrate 100 to define active regions 105 that are arranged in a two dimensional array. A plurality of gate electrodes, i.e., a plurality of word lines 130 intersect the active regions 105 and the device isolation region 110. The gate electrodes 130 are parallel to each other in a column direction (Y-axis direction). The active regions 105 are parallel to each other in a row direction (X-axis direction) and are each intersected by the gate electrodes (or word lines) 130 (e.g., a pair of gate electrodes 130 as shown in FIG. 6). Accordingly, each active region 105 is divided into three regions: a common source region 150s in the active region 105 between the pair of gate electrodes 130, and drain regions 150d in the active regions 105 on opposite sides of the common source region 150s. The cell transistors are formed at the intersection points of the gate electrodes 130 and the active regions 105, and are thereby arranged in two dimensions along the column (Y-axis) and row (X-axis) directions.

The resultant substrate including the cell transistors is covered with a lower interlayer insulating film having a sequentially stacked structure of a first lower interlayer insulating film 160 and a second lower interlayer insulating film 190. Contact plugs 170 penetrate the first lower interlayer insulating film 160 to connect to the common source region 150s and the drain region 150d. A source line 180s is formed on the first lower interlayer insulating film 160 and connects to the contact plugs 170, which, in turn, are connected to the common source region 150s. Each of the source line 180s may connect a plurality of common source regions 150s placed at one side of the word line 130 one another. Accordingly, the source lines 180s are parallel to the word lines 130.

A first metallic pattern 180 is formed on the first lower interlayer insulating film 160 and connected with the drain region 150d through the contact plug 170. The first metallic pattern 180 and the source line 180s may have the same thickness and be the same type of material. The second lower interlayer insulating film 190 covers the resultant structure including the first metallic pattern 180 and the source line 180s. Via plugs 200 penetrate the second lower interlayer insulating film 190 to connect to an upper surface of the first metallic pattern 180.

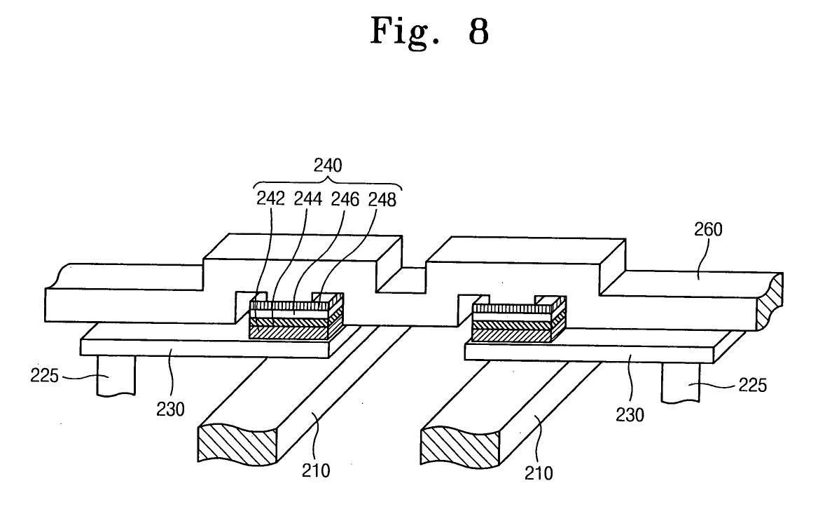

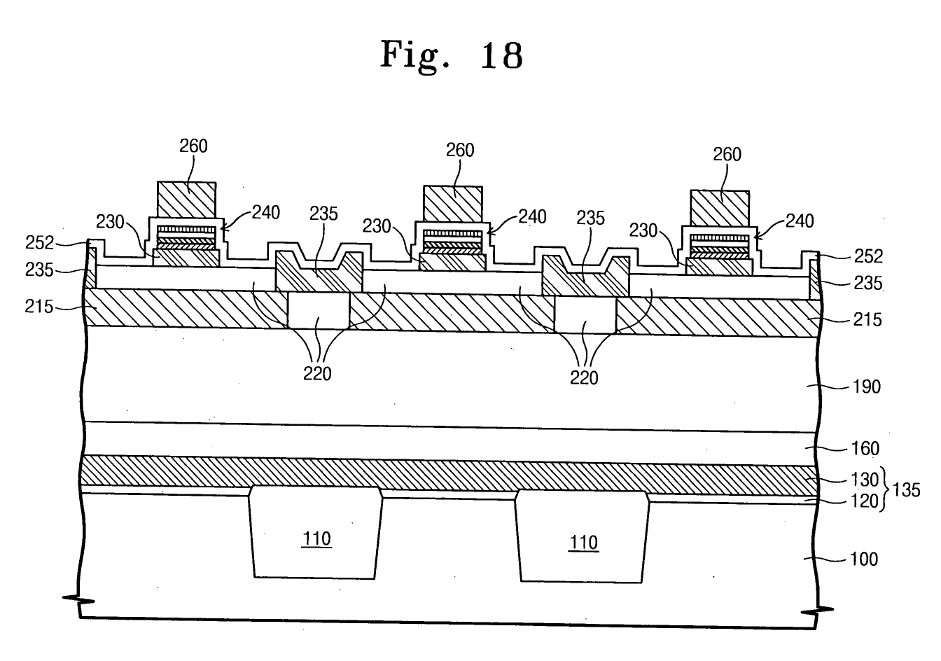

The digit lines 210 are, desirably, parallel to the word lines 130. But, the digit lines 210 may intersect the word lines 130 at an oblique angle. The digit lines 210 also intersect the active regions 105 and the device isolation region 110 on the second lower interlayer insulating film 190. As used herein, lines “intersect” by crossing paths, although they may not be directly connected to each other. For example, as shown in FIGS. 8A and 18, digital lines 210 intersect word lines 130 by crossing over the word lines 130. According to the first embodiment of the present invention, the digit lines 210 are arranged in a zigzag pattern parallel to each other to provide sufficient spatial distance between them. A second metallic pattern 215 may be formed on the underlying second lower interlayer insulating film 190 and spaced apart from the digit lines 210, and connected to drain region 150d through the via plug 200. The second metallic pattern 215 and the digit line 210 may have the same thickness and be the same type of material.

The resultant substrate including the digit lines 210 is covered with an upper interlayer insulating film. The upper interlayer insulating film may have a sequentially stacked structure of a first upper interlayer insulating film 220 and a second upper interlayer insulating film 250. A lower electrode 230 is formed on the first upper interlayer insulating film 220 and intersects the digit lines 210. The lower electrode 230 is connected to the second metallic pattern 215 through a conductive pattern 225 that penetrates the first upper interlayer insulating film 220.

Magnetic tunnel junctions 240 are formed on the top surface of the lower electrode, and over a top surface of the digit lines 210. The magnetic tunnel junctions 240 are formed at intersection points of the digit lines 210 and the lower electrodes 230.

The magnetic tunnel junctions 240 may each include a stacked structure of a pinning layer 242, a fixed layer 244, an insulation layer 246 and a free layer 248. The pinning layer may be formed from an anti-ferromagnetic material, such as one or more of the materials IrMn, PtMn, MnS, MnO, MnTe, MnF₂, FeF₂, FeCl₂, FeO, CoCl₂, CoO, NiCl₂ and Cr. The fixed layer 244 and the free layer 248 may be formed from one or more ferromagnetic materials, such as Fe, Co, Ni, Gd, Dy, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂. The fixed layer may have a multi-layer structure with a Ruthenium (Ru) layer (or other material) interposed between two ferromagnetic material layers.

The semiconductor substrate including the magnetic tunnel junctions 240 are conformally covered with the second upper interlayer insulating film 252. Accordingly, an exposed, or top, surface of the second upper interlayer insulating film 252 is not planar at least in a major region adjacent to, and on, the magnetic tunnel junction 240. The second upper interlayer insulating film 252 defines an opening 254 that exposes a first surface, or top surface, of the magnetic tunnel junction 240.

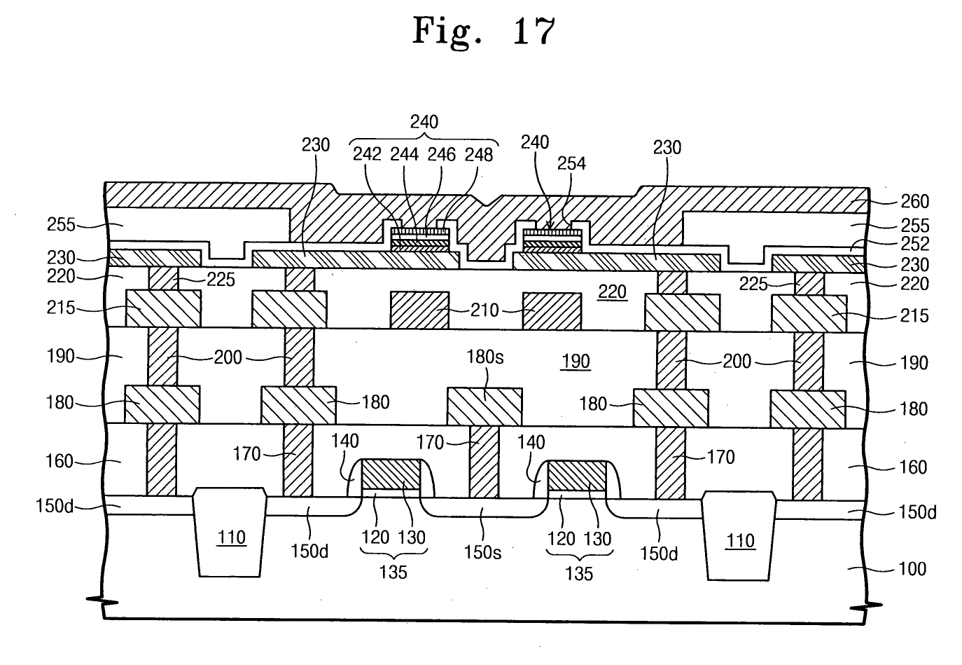

The bit line 260 is formed on the second upper interlayer insulating film 252 and in the opening 254 to directly contact the top surface of the magnetic tunnel junction 240. As shown in FIG. 17, the second upper interlayer insulating film 252 is not planar because of, for example, bumps (or protrusions) caused by the underlying magnetic tunnel junctions 240 and the lower electrodes 230. Because the second upper interlayer insulating film 252 is not planar, at least a lower surface of the bit line 260 is also not planar. When the bit line 260 is formed on the second upper interlayer insulating film 252 and on the magnetic tunnel junction 240, it forms a recessed portion that at least partially covers a first surface, or top surface, and side surfaces of the magnetic tunnel junction 240. Accordingly, the bit line 260 has a recessed portion in which the magnetic tunnel junction 240 is at least partially disposed within. The recessed portion of the bit line 260 also corresponds to an intersection of bit line 260 with a digit line. The bit line may be formed so that a majority of a side surface of the magnetic tunnel junction 240 is disposed in the recessed portion of the bit line 260.

Referring to FIG. 17, according to other embodiments of the present invention, a third interlayer dielectric 255 is interposed between the bit line 260 and the second upper interlayer insulating film 252. The third interlayer dielectric 255 defines an opening that exposes the top part of the magnetic tunnel junction 240. A top surface of the third interlayer dielectric 255 is planar, which reduces non-planar affects, or ununiformity, that may be caused by the bumps in the second upper interlayer insulating film 252 from the underlying magnetic tunnel junctions 240 and the lower electrodes 230. Accordingly, the bit line 260, which is formed on the planar surface of the third interlayer dielectric 255 and the second upper interlayer insulating film 252, has an increased planar upper surface compared to the bit line 260 that shown in FIG. 16. The more planar bit line 260 of FIG. 17 may have a reduced length compared to the bit line 260 of FIG. 16, and may facilitate removal of undesired materials in subsequent etching processes.

FIG. 8 is a perspective view of a magnetic memory according to some embodiments of the present invention. Referring to FIG. 8, the bit line 260 cross over, and thereby intersects, the digit lines 210. Magnetic tunnel junctions 240 are between the bit line 260 and the digit lines 210 at the intersections. The bit line 260 has recessed portions at the intersections with the digit lines 210. The magnetic tunnel junctions 240 are at least partially disposed in the recessed portions of the bit lines 260. A majority of a side surface of the magnetic tunnel junctions 240 may be disposed in the recessed portions of the bit lines 260, for example, as shown in FIG. 8.

The bit line 260 may be electrically connected to the free layer 248, and may be formed directly on the free layer 248. The bit line 260 is electrically isolated from the fixed layer 244. Such electrical connectivity and isolation between the bit line 260 and portions of the magnetic tunnel junctions 240 may be provided by the second top interlayer dielectric 252 (FIG. 16). The second top interlayer dielectric 252 (FIG. 16) defines the opening 254 that exposes the top surface of the magnetic tunnel junction 240 and conformally covers the side surfaces of the magnetic tunnel junctions 240 and the semiconductor substrate. The thickness of the second top interlayer dielectric 252 may be, for example, about 10-3000 Angstroms.

In the magnetic memory with the magnetic tunnel junction 240, the efficiency of write operations may be related to the intensity of the magnetic field that is formed by the bit line 260 and the digit line 210. Because the magnetic tunnel junctions 240 are at least partially disposed in the recessed portions of the bit lines 260, there may be a corresponding increase in an amount of the bit line 260 that faces the magnetic tunnel junctions 240, and which may increase the intensity of the magnetic field from the bit line 260 that is applied to the free layer 248 of the magnetic tunnel junctions 240. Increasing the intensity of the magnetic field may allow a decrease in the electric current in the bit line 260 for write operations, may reduce the amount of electromagnetic disturbance that is caused to non-selected cells, and may decrease the power consumed for a write operation.

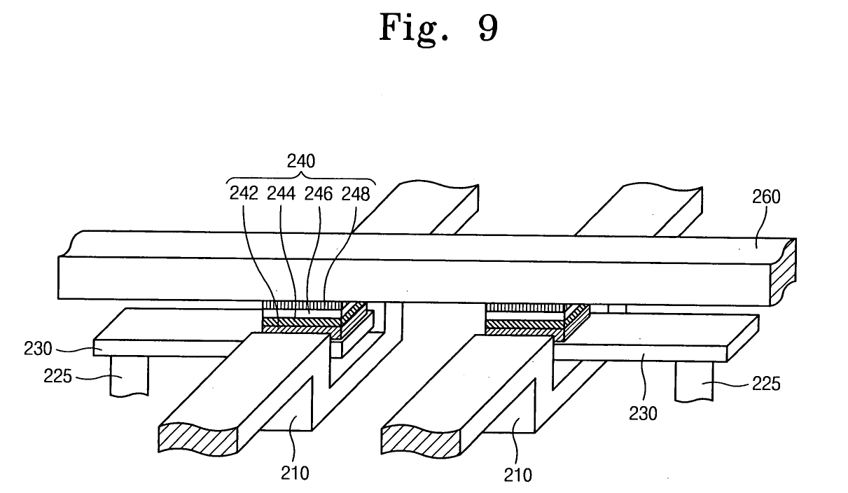

FIG. 9 is a perspective view of a magnetic memory according to some other embodiments of the present invention. FIG. 9 is similar to FIG. 8, except that the digit lines 210 have recessed portions at the intersections with the bit lines 260. The magnetic tunnel junctions 240 are at least partially disposed in the recessed portions of the digit lines 210. A majority of the side surface of the magnetic tunnel junctions 240 may be disposed in the recessed portion of the digit lines 210, such as, for example, as shown in FIG. 9.

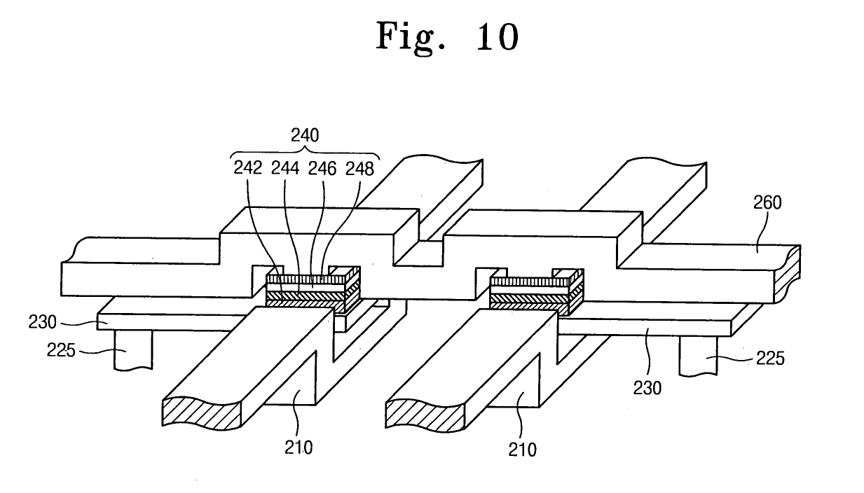

FIG. 10 is a perspective view of a magnetic memory according to some other embodiments of the present invention. FIG. 10 is similar to FIGS. 8 and 9, except that both the bit line 260 and the digit lines 210 each have an oppositely recessed portion at an intersection of the bit line 260 and the digit lines 210. The magnetic tunnel junctions 240 are at least partially disposed in the recessed portions of the bit lines 260 and the recessed portions of the digit lines 210. A majority of the side surface of the magnetic tunnel junctions 240 may be disposed in the recessed portions of the bit lines 260 and the recessed portions of the digit lines 210, such as, for example, as shown in FIG. 10.

Although only one bit line 260 is shown in FIGS. 8-10, it is to be understood that the magnetic memory may include a plurality of the bit lines 260 as described herein.

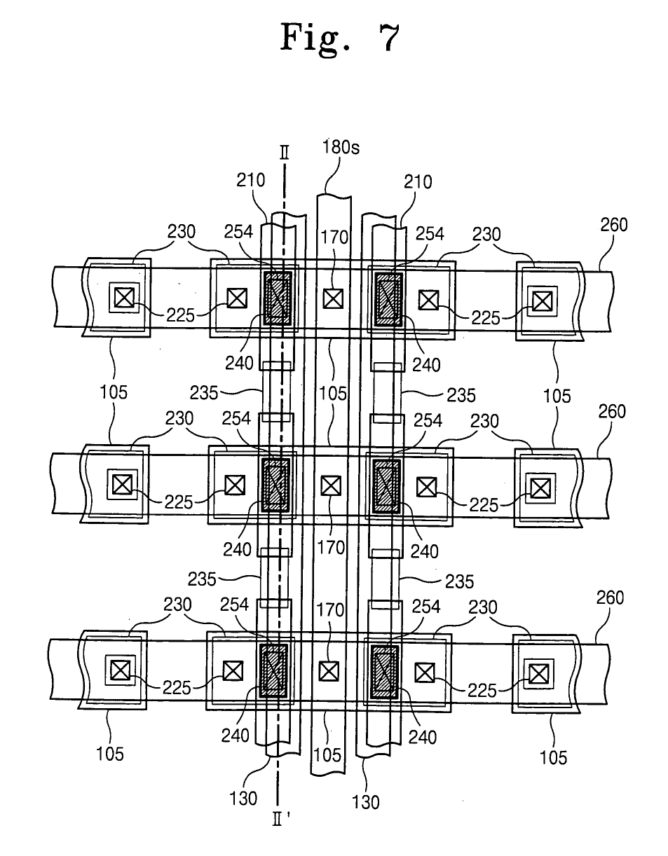

FIG. 7 is a cross-sectional view of a part of a cell array of a MRAM according to some embodiments of the present invention. These embodiments are described with reference to FIGS. 5, 7, and 18. These embodiments are similar to those described with regard to FIGS. 6, 6, and 16, except that the digit lines (DL) and/or the bit lines (BL) are arranged differently. Accordingly, the common description of these embodiment is not repeated here for brevity, and only the differences are discussed below.

Referring to FIG. 5, FIG. 7 and FIG. 18, a connection pattern 235 is connected to the top surface of the digit lines 210. Referring to FIG. 18, the digit lines 210 may be formed with the connection pattern 235 and a second metallic pattern 215. The second metallic pattern 215 may be under the connection pattern 235, and on a top surface of the isolation layer 110. Connection patterns 235 are formed between the bit lines 260, and have a non-planar exposed upper surface on which the second upper interlayer insulating film 252 is formed. The digit lines 210 can be made non-planar (i.e., bumpy) due to the connection pattern 235 have a non-planar upper surface. The connection patterns 235 may be formed when the lower electrodes 230 are formed, and/or may be subsequently formed when the bit lines 260 and/or the via plug 200 are formed.

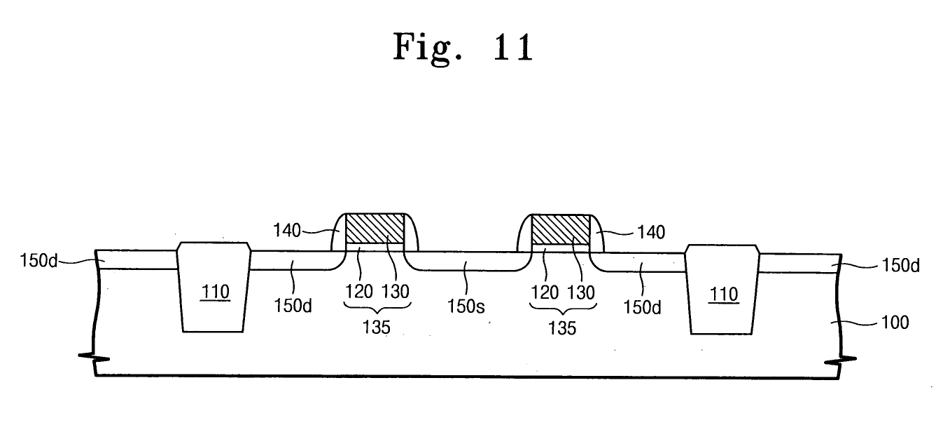

FIG. 11-FIG. 16 are sectional views along line I-I′ of FIG. 6 of operations for fabricating MRAMS with magnetic tunnel junctions according to various embodiments of the present invention.

Referring to FIG. 11, the device isolation region 110 is formed in the semiconductor substrate 100 to define the plurality of active regions 105. The gate insulating layer and the gate conductive layer are sequentially formed on the surface of the resultant substrate 100 including the active regions 105. The gate conductive film and the underlying gate insulating film are sequentially patterned to form a plurality of gate patterns 135 that are parallel to one another. The plurality of gate patterns 135 intersects the device isolation region 110 and the active regions 105. The gate patterns 135 each include the sequentially stacked structure of the gate insulating pattern 120 and the gate electrode 130. The active regions 105 each intersect the pair of gate electrodes 130. The gate patterns 135 may also include a capping pattern formed on the underlying gate electrode 130, such as a word line.

The gate pattern 135 and the device isolation region 110 are used as ion implanting masks for selectively implanting ions into the active regions 105. As a result thereof, three impurity regions are formed in the active region 105. As shown, a middle-positioned impurity region among three impurity regions indicates the common source region 150s, and other impurity regions indicate the drain regions 150d.

Accordingly, a pair of cell transistors is respectively formed in one active region 105. As a result, the cell transistors are arrayed in two dimensions along the row and the column directions in the semiconductor substrate. Next, a spacer 140 is formed on sides of the gate pattern 135.

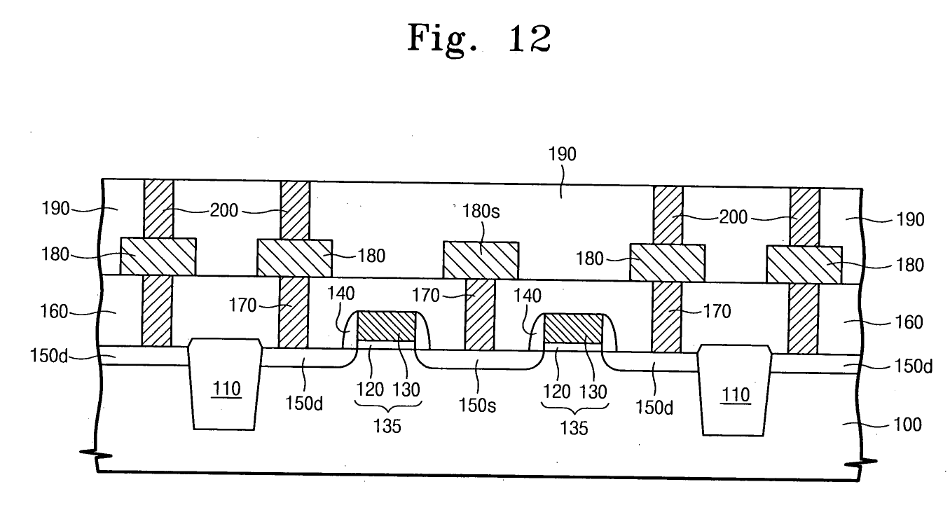

Referring to FIG. 12, the first lower interlayer insulating film 160 is formed on the whole surface of the resultant substrate including the spacer 140. The first lower interlayer insulating film 160 is patterned to form contact holes that expose the source/drain regions 150s and 150d. The contact plugs 170 are formed to fill the contact holes and connect to the source/drain regions 150s and 150d. A first metallic layer is formed on the whole surface of the resultant substrate including the contact plugs 170. The first metallic layer is patterned to form the source line 180s and the first metallic patterns 180 covering the underlying contact plugs 170. The source line 180s is connected to the underlying common source regions 150s through the contact plugs 170. The common source regions 150s may be formed in the active region 105 between the pair of the gate patterns 135, thereby connecting to one another through the source line 180s in the column direction. The first metallic patterns 180 with a width greater than the contact plugs 170 are spaced apart from, and isolated from, the source line 180s.

A second lower interlayer insulating film 190 is formed on the whole surface of the resultant substrate including the source line 180s and the first metallic patterns 180. The first and the second interlayer insulating films 160 and 190 form an interlayer insulating film. The second lower interlayer insulating film 190 is patterned to form a first via hole exposing a top surface of the first metallic pattern 180. The first via hole exposes the top surface of the source line 180s in a predetermined region. The plurality of via plugs 200 are formed in, and may fill, the first via holes.

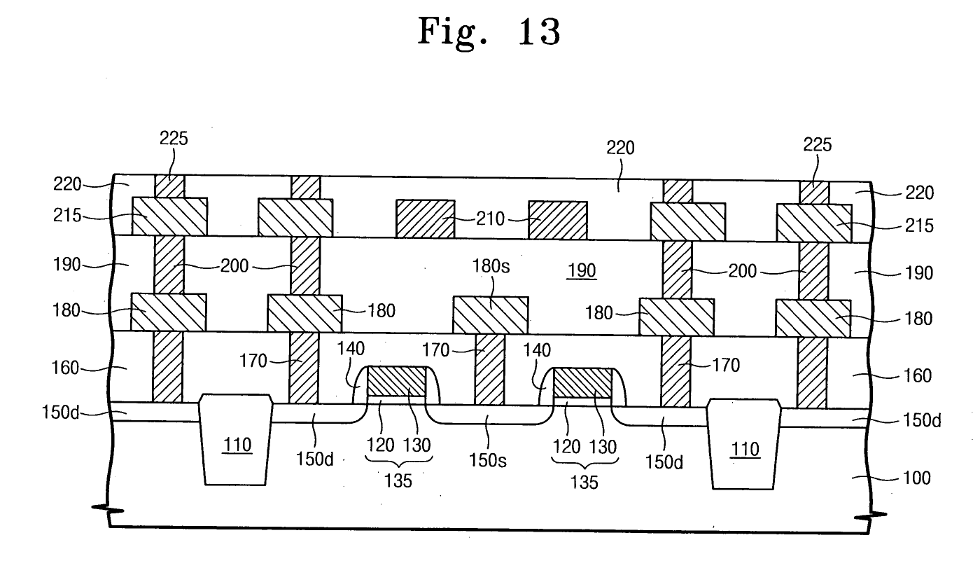

Referring to FIG. 13, a second metallic layer is formed on the whole surface of the resultant substrate including the via plugs 200. The second metallic layer is patterned to form the plurality of second metallic patterns 215 and the digit lines 210. The second metallic pattern 215 is formed to cover the top surface of the via plugs 200. The digit lines 210 intersect the active regions 105 and the device isolation region 110, and may intersect the word lines 130 at a right angle or an oblique angle.

The first upper interlayer insulating film 220 is formed on the whole surface of the resultant substrate including the second metallic patterns 215 and the digit lines 210. Forming the first upper interlayer insulating film 220 can additionally include the process of regularizing a thickness of the first upper interlayer insulating film 220 on the digit line 210 by, for example, a planarization process.

The first upper interlayer insulating film 220 is patterned to form a second via hole exposing the upper surface of the second metallic pattern 215. After that, the second via hole is filled to form the metallic patterns 225 connected to the drain region 150d.

Alternatively, the second metallic film may be formed to fill the via hole, so that the via plugs 200 can be formed at the same time as the second metallic pattern 215 and the digit line 210.

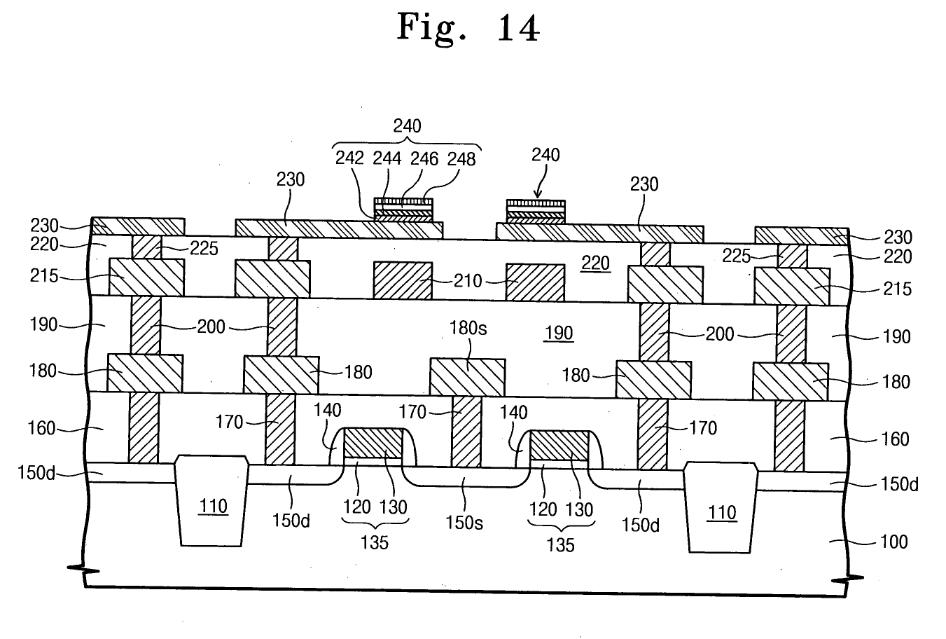

According to another embodiment of the present invention, and with reference to FIG. 14, the digit lines 210 may be second metallic patterns which are cut over the isolation layer 110. Referring to FIG. 14, the lower electrode 230 connects to the upper surface of the conductive pattern 225 and to pass over the digit line 210. The digit line 210 and the lower electrode 230 are spaced apart from each other by a predetermined height, which may be the thickness of the conductive pattern 225. The conductive pattern 225 can be formed at the same time that the lower electrode 230 is formed to fill the second via hole.

The magnetic tunnel junction 240 may include a sequentially stacked structure of the pinning layer 242, the fixed layer 244, the insulating layer 246 and the free layer 248. The pinning layer 242 may be formed from one of more anti-ferromagnetic materials, including IrMn, PtMn, MnO, MnS, MnTe, MnF₂, FeF₂, FeCl₂, FeO, CoCl₂, CoO, NiCl₂, NiO, and/or Cr. The fixed layer 244 and the free layer 248 may each be formed from one or more ferromagnetic materials, including Fe, Co, Ni, Gd, Dy, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. The fixed layer 244 may have a three-layered structure in which a Ruthenium layer (Ru) is interposed between a ferromagnetic upper fixed layer and a ferromagnetic lower fixed layer. The insulating layer 246 may be conformally formed with a regular thickness. For example, the insulating layer 246 may be formed using a Chemical Vapor Deposition (CVD) process or an Atomic Layer Deposition (ALD) process.

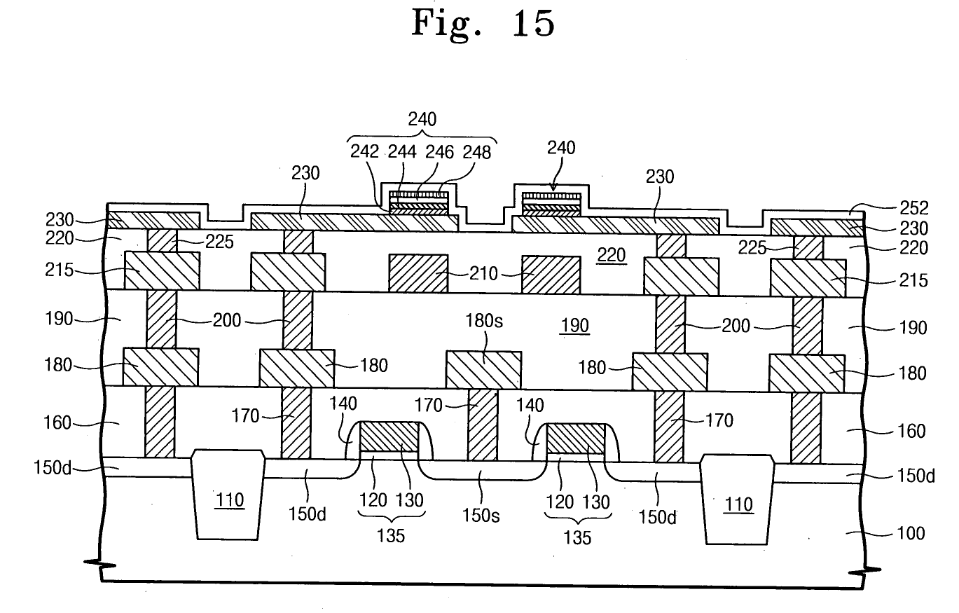

Referring to FIG. 15, a second upper interlayer insulating film 252 is formed on the surface of the semiconductor substrate including the lower electrode 230 and the magnetic tunnel junction 240. The second upper interlayer insulating film 252 may be conformally formed with a regular thickness. The thickness of the second interlayer insulating film 252 may be, for example, about 10-3000 Angstroms. Depending upon the thickness of the second interlayer insulating film 252, the upper exposed surface of the second interlayer insulating film 252 is not planar due to bumps caused by the magnetic tunnel junction 240 and the lower electrode 230. The second upper interlayer insulating film 252 may be, for example, silicon oxide, silicon nitride and/or silicon oxynitride, and/or may be another insulation material.

Referring to FIG. 16, an opening 254 which exposes the top surface of the magnetic tunnel junction 240 is formed by patterning the second upper interlayer insulating film 252. Then, a bit line 260, which is connected to the magnetic tunnel junction exposed through the opening 254, is formed. The bit line 260 intersects over the word line 130 and the digit lines 210.

According to some embodiments of the present invention, the bit line 260 is not planar, having a bumpy shape that follows the contour of the second upper interlayer insulating film 252. The bit line 260 includes recessed portions, and the magnetic tunnel junction 240 are at least partially disposed in the recessed portions of the bit line 260.

According to some further embodiments of the present invention, before the bit line 260 is formed, the third upper interlayer insulating film 255 is formed to cover the surface of the semiconductor substrate including the second upper interlayer insulating film 252. An exposed upper surface of the third interlayer insulating film 255 may be planarized, such as by an etching process. An opening is formed by patterning the third interlayer insulating film 255 to expose the second top interlayer insulating film 252 on the topsides and peripherals of the magnetic tunnel junction 240. The bit line 260 intersects the opening in the third interlayer insulating film 255.

In some other embodiments of the present invention, the second upper interlayer insulating film 252 may be formed after the third interlayer insulating film 255 is formed. The third interlayer insulating film 255 may be planarized by etching until the top surface of the magnetic tunnel junction 240 is exposed. The conductive material layer may be also formed on the free layer 248 to avoid etching damage to the free layer 248.

The intensity of the magnetic field that may occur in a magnetic memory according to the prior art and a magnetic memory according to various embodiments of the present invention is shown in table two, as generated by computer simulations thereof. The values of the table represent intensities of magnetic field applied at the magnetic tunnel junction 40, where the intensities of magnetic field are induced by the bit line.

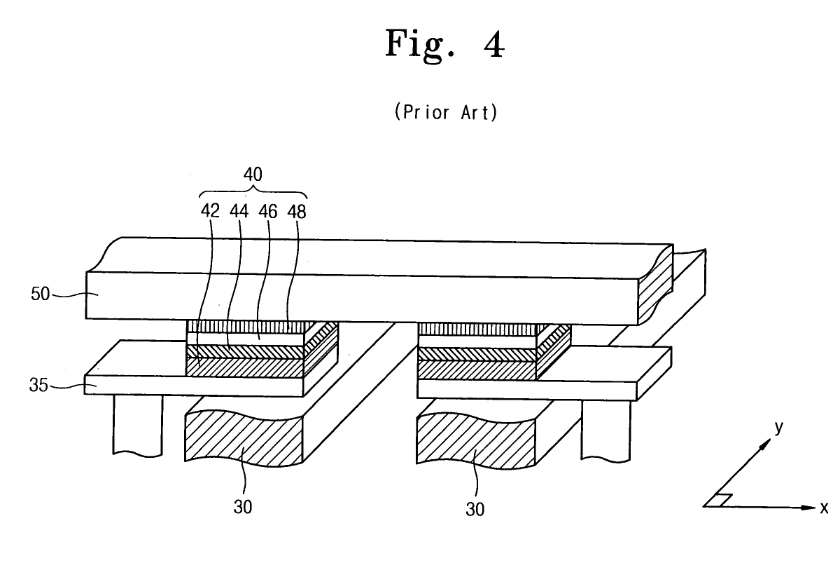

TABLE 2

| | The prior art | Various embodiments |
|---|---|---|
| | memory as | of the invention as |
| | shown in FIG. 4 | shown in FIG. 8 |
| Intensity of magnetic field | 5.61 | 13.59 |
| (Oe) | | |

The value for the prior art memory, 5.61 Oe, represents the intensity in the case that the magnetic tunnel junction 40 is disposed 0.2 micrometers away from the bit line 50, when an electric current into the bit line is 1 mA. In this simulation for the prior art memory, the width and height of the bit line 50 are assumed to be 0.8 micrometers and 0.3 micrometers, respectively.

As shown in FIG. 8, an magnetic field intensity of 13.59 Oe may be obtained by the bit line 260 having the recessed portion in which the magnetic tunnel junction 240 is at least partially disposed. The isolation distance from the top part of the magnetic tunnel junction 260 to the bit line 240 is assumed to be 0.2 micrometers, which is the same assumption as for the prior art magnetic memory. The isolation distance from the sidewalls of the magnetic tunnel junction 260 to the bit line 240 is assumed to be 0.4 micrometers. Therefore, according various embodiments of the present invention may provide a 2.4 times increase in magnetic field intensity relative to some prior art magnetic memories.

It should be noted that many variations and modifications might be made to the embodiments described above without substantially departing from the principles of the present invention. All such variations and modifications are intended to be included herein within the scope of the present invention, as set forth in the following claims.

What is claimed is:

1. A magnetic memory comprising:
a digit line;
a bit line, wherein the bit line has a recessed portion at an intersection with the digit line; and
a magnetic tunnel junction between the bit line and the digit line, wherein the magnetic tunnel junction is at least partially disposed in the recessed portion of the bit line.

2. The magnetic memory of claim 1, wherein a majority of a side surface of the magnetic tunnel junction is disposed in the recessed portion of the bit line.

3. The magnetic memory of claim 1, further comprising:
a plurality of digit lines;
a plurality of bit lines, wherein each of the bit lines has a recessed portion at an intersection with the digit lines; and
a plurality of magnetic tunnel junctions, wherein each of the magnetic tunnel junctions is between one of the bit lines and one of the digit lines, and wherein the magnetic tunnel junctions are at least partially disposed in the recessed portion of the bit lines.

4. The magnetic memory of claim 3, wherein the plurality of digit lines comprise:
metal patterns under the magnetic tunnel junctions; and
connection patterns that electrically connect the metal patterns, wherein the connection patterns are on opposite sides of the magnetic tunnel junction and above than the metal patterns.

5. The magnetic memory of claim 1, further comprising a first insulation layer between the bit line and the magnetic tunnel junction, wherein the first insulation layer defines an opening that exposes at least a portion of a first surface of the magnetic tunnel junction, and wherein the bit line contacts the first surface of the magnetic tunnel junction through the opening in the first insulating layer.

6. The magnetic memory of claim 1, further comprising a second insulation layer between the bit line and a major portion of the first insulating layer, wherein the second insulation layer has a planar upper surface and defines an opening though which the bit line is directly on the first insulating layer in a region adjacent to and over the magnetic tunnel junction.

7. The magnetic memory of claim 1, wherein the magnetic tunnel junction is electrically connected to the bit line and is electrically insulated from the digit line.

8. The magnetic memory of claim 1, wherein the magnetic tunnel junction comprises a pinning layer, a fixed layer, an insulation layer, and a free layer, which are stacked sequentially.

9. The magnetic memory of claim 8, wherein the pinning layer is at least one of a group of antiferromagnetic materials including IrMn, PtMn, MnS, MnO, MnTe, MnF₂, FeF₂, FeCl₂, FeO, CoCl₂, CoO, NiCl₂, NiO and Cr.

10. The magnetic memory of claim 8, wherein the fixed layer and the free layer are each at least one of a group of ferromagnetic materials including Fe, Co, Ni, Gd, Dy, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂.

11. The magnetic memory of claim 8, wherein the fixed layer comprises a ferromagnetic layer, a Ruthenium layer and a ferromagnetic layer.

12. The magnetic memory of claim 1, further comprising:
a plurality of digit lines;
a plurality of bit lines, wherein each of the bit lines has a recessed portion at an intersection with the digit lines;
a plurality of magnetic tunnel junctions, wherein each of the magnetic tunnel junctions is between one of the bit lines and one of the digit lines, wherein the magnetic tunnel junctions are at least partially disposed in the recessed portion of the bit lines;
a semiconductor substrate, wherein the bit lines, the digit lines and the magnetic tunnel junctions are on the semiconductor substrate;
a plurality of cell transistors in the semiconductor substrate and arranged along row and column directions, wherein each of the cell transistors comprises a gate electrode, a source region, and a drain region; and
a plurality of word lines connected to the gate electrodes of the cell transistors.

13. The magnetic memory of claim 12, wherein the digit lines are parallel to the word lines, and wherein the bit lines are connected to the drain regions of the cell transistors through the magnetic tunnel junction.

14. A magnetic memory comprising:
a bit line;
a digit line, wherein the digit line has a recessed portion at an intersection with the bit line; and
a magnetic tunnel junction between the bit line and the digit line, wherein the magnetic tunnel junction is at least partially disposed in the recessed portion of the digit line.

15. The magnetic memory of claim 14, wherein a majority of a side surface of the magnetic tunnel junction is disposed in the recessed portion of the digit line.

16. The magnetic memory of claim 14, further comprising:
a plurality of bit lines;
a plurality of digit lines, wherein each of the digit lines has a recessed portion at an intersection with the bit lines; and
a plurality of magnetic tunnel junctions, wherein each of the magnetic tunnel junctions is between one of the bit lines and one of the digit lines, and wherein the magnetic tunnel junctions are at least partially disposed in the recessed portion of the digit lines.

17. A magnetic memory comprising:
a digit line;
a bit line, wherein the bit line and the digit line each have an oppositely recessed portion at an intersection of the digit line and the bit line; and
a magnetic tunnel junction between the bit line and the digit line, wherein the magnetic tunnel junction is at least partially disposed in the recessed portion of the bit line and in the recessed portion of the digit line.

18. The magnetic memory of claim 17, wherein a majority of a side surface of the magnetic tunnel junction is disposed in the recessed portion of the bit line and in the recessed portion of the digit line.

19. The magnetic memory of claim 17, further comprising:
a plurality of digit lines;
a plurality of bit lines, wherein each of the bit lines and each of the digit lines have an oppositely recessed portion at an intersection of the digit lines and the bit lines; and
a plurality of magnetic tunnel junctions, wherein the magnetic tunnel junction is at least partially disposed in the recessed portion of the bit lines and in the recessed portion of the digit lines.

20. A method for fabricating a magnetic memory comprising:
forming a digit line;
forming an first interlayer insulating film on the digit line;
forming a magnetic tunnel junction on the first interlayer insulating film; and
forming a bit line directly on a first surface of the magnetic tunnel junction, wherein the bit line has a recessed portion at an intersection with the digit line, and wherein the magnetic tunnel junction is at least partially disposed in the recessed portion of the bit line.

21. The method of claim 20, wherein forming a bit line directly on a first surface of the magnetic tunnel junction comprises forming the bit line so a majority of a side surface of the magnetic tunnel junction is disposed in the recessed portion of the bit line.

22. The method of claim 20, further comprising:
forming a plurality of digit lines;
forming the first interlayer insulating film on the digit lines;
forming a plurality of magnetic tunnel junctions on the first interlayer insulating film; and
forming a plurality of bit lines, wherein each of the bit lines is directly on a first surface of a different one of the magnetic tunnel junctions, wherein each of the bit lines has a recessed portion at an intersection with the digit lines, and wherein the magnetic tunnel junctions are at least partially disposed in the recessed portion of the bit lines.

23. The method of claim 22, wherein the forming a plurality of digit lines comprises:
forming metallic patterns that intersect the magnetic tunnel junctions; and
forming connection patterns on both sides of the magnetic tunnel junctions and electrically connected to the metallic patterns.

24. The method of claim 22, wherein forming a plurality of digit lines comprises forming the plurality of digit lines on a semiconductor substrate.

25. The method of claim 24, wherein before forming the plurality of digit lines on a semiconductor substrate, further comprising:
forming an isolation layer defining active regions in a predetermined region of the semiconductor substrate;
forming a plurality of word lines that intersect the active regions;
forming source/drain regions in the active region between the word lines; and
forming a second interlayer insulating film on the semiconductor substrate and the source/drain regions.

26. The method of claim 25, wherein before forming a plurality of magnetic tunnel junctions on the first interlayer insulating film, further comprising forming a conductive interconnection that penetrates the upper interlayer insulating film and the lower interlayer insulating film and is electrically connected to the drain region.

27. The method of claim 25, wherein forming a second interlayer insulating film on the semiconductor substrate and the source/drain regions comprises sequentially forming a third interlayer insulating film and a fourth interlayer insulating film on the semiconductor substrate and the source/drain regions.

28. The method of claim 27, wherein forming a third interlayer insulating film and a fourth interlayer insulating film comprises:
forming contact plugs that penetrate the third interlayer insulating film and electrically connect to the source/drain regions;
forming a first metal pattern that intersects the contact plugs on the third interlayer insulating film, forming the fourth interlayer insulating film; and
forming via plugs that penetrate the fourth interlayer insulating film and electrically connect to the first metallic pattern, wherein the first metallic pattern forms a source line that is connected to the source regions through the contact plugs and forms a pad for connecting the via plugs to the contact plugs.

29. The method of claim 20, wherein before forming a bit line directly on a first surface of the magnetic tunnel junction, further comprising:
forming a first insulation layer that conformally covers the surface of the resultant structure including the magnetic tunnel junction; and
patterning the first insulation layer to form an opening that exposes the first surface of the magnetic tunnel junction, wherein the bit line is formed directly on the first surface of the magnetic tunnel junction through the opening in the first insulation layer.

30. The method for fabricating the magnetic memory of claim 20, wherein before forming a bit line directly on a first surface of the magnetic tunnel junction, further comprising:
forming a second insulation layer covering a surface of the resultant structure including the magnetic tunnel junction;
etching the second insulation layer to form a planar exposed surface; and
patterning the second insulation layer to form an opening that exposes side surfaces and the first surface of the magnetic tunnel junction, wherein forming a bit line directly on a first surface of the magnetic tunnel junction comprises forming the bit line in the opening of the second insulation layer and contacting the first surface of the magnetic tunnel junction.

31. A method for fabricating a magnetic memory comprising:
forming a digit line;
forming an first interlayer insulating film on the digit line;
forming a magnetic tunnel junction on the first interlayer insulating film; and
forming a bit line directly on a first surface of the magnetic tunnel junction, wherein the digit line has a recessed portion at an intersection with the bit line, and wherein the magnetic tunnel junction is at least partially disposed in the recessed portion of the digit line.

32. A method for fabricating a magnetic memory comprising:
forming a digit line;
forming an first interlayer insulating film on the digit line;
forming a magnetic tunnel junction on the first interlayer insulating film; and
forming a bit line directly on a first surface of the magnetic tunnel junction, wherein the bit line and the digit line each have an oppositely recessed portion at an intersection of the bit line and the digit line, and wherein the magnetic tunnel junction is at least partially disposed in the recessed portion of the bit line and in the recessed portion of the digit line.

33. A magnetic memory comprising:
a digit line;
a bit line that intersects the digit line at an intersection, wherein at least one of the bit line and the digit line includes a recessed portion at the intersection; and
a magnetic tunnel junction between the bit line and the digit line, wherein the magnetic tunnel junction is at least partially disposed in the recessed portion.
